(19) United States
(12) Patent Application Publication
(10) Pub. No.: US 2021/0167683 A1
(43) Pub. Date: Jun. 3, 2021

(54) Voltage Supply Device having an Intermediate Circuit, A Power Converter and Braking Chopper

(71) Applicant: Siemens Mobility GmbH, Muenchen, Bayern (DE)

(72) Inventors: Vladislav DAMEC, Hlohovec (CZ); Stefan Hans Werner SCHÖNEWOLF, Nürnberg (DE)

(21) Appl. No.: 17/048,302

(22) PCT Filed: Apr. 16, 2019
(86) PCT No.: PCT/EP2019/059749

§ 371 Date: Oct. 16, 2020

(30) Foreign Application Priority Data
Apr. 17, 2018 (EP) 18167792.3

(51) Int. Cl. H02M 1/32; H02M 5/458; H02M 1/14; H01L 29/16; B60L 13/00

(52) U.S. Cl. CPC H02M 1/32; H02M 5/458; H02M 1/14; B60L 2210/20; B60L 13/006; H02M 2001/322; B60L 2200/26; H01L 29/1608

(57) ABSTRACT

A voltage supply device includes at least one intermediate circuit that has at least one intermediate circuit capacitor, at least one power converter, wherein the power converter is connected to the connections of the intermediate circuit such that the power converter can be supplied with electrical energy from the intermediate circuit capacitor, and includes at least one braking chopper that is connected to the connections of the intermediate circuit capacitor such that electrical energy from the intermediate circuit capacitor can be converted into thermal energy by the braking chopper, where the power converter is equipped with at least one semiconductor switch that is clocked at a higher rate, in particular based on SiC, while the braking chopper is equipped with at least one semiconductor switch that is clocked at a lower rate, in particular based on Si.

### CROSS-REFERENCE TO RELATED APPLICATIONS

This is a U.S. national stage of application No. PCT/EP2019/059749 filed 16 Apr. 2019. Priority is claimed on European Application No. 18167792 filed 17 Apr. 2018, the content of which is incorporated herein by reference in its entirety.

### BACKGROUND OF THE INVENTION

### 1. Field of the Invention

The invention relates to a voltage supply device having at least one intermediate circuit comprising at least one intermediate circuit capacitor, at least one power converter, where the power converter is connected to the connections (e.g., terminals) of the intermediate circuit such that the power converter can be supplied with electrical energy from the intermediate circuit capacitor, and/or that the power converter can feed electrical energy into the intermediate circuit, and includes at least one braking chopper that is connected to the connections of the intermediate circuit capacitor such that electrical energy of the intermediate circuit capacitor can be converted into thermal energy by the braking chopper.

So that the power converter can be supplied with electrical energy from the intermediate circuit capacitor and/or so that the power converter can feed electrical energy into the intermediate circuit, the intermediate circuit is connected to the supplying power grid via, e.g., a line choke in the DC vehicle or via a further suitable power converter.

### 2. Description of the Related Art

Power converters are devices for converting a supplied type of electrical current (direct current, alternating current) into the respective other type, or for converting alternating current into an alternating current with a changed absolute value and/or changed frequency and/or changed phase angle. The conversion is accomplished via electronic components based on semiconductors, i.e., with diodes, transistors or thyristors, in this context in particular via metal-oxide-semiconductor field-effect transistors (MOSFETs), insulated-gate bipolar transistors (IGBTs) and integrated gate-commutated thyristor (IGCTs).

Power converters for converting direct current into alternating current are referred to as inverters or pulse width modulated inverters. Power converters for converting alternating current into direct current are referred to as rectifiers or H bridges.

Power converters for converting alternating current into an alternating current with at least changed frequency are referred to as frequency converters.

In electrically operated railroads, various combinations of the abovementioned components (H bridges, pulse width modulated inverters) are used under the term traction power converters, to convert the current from the respective railroad power system of the overhead line or of the power rail into the three-phase current for the three-phase current drive motors that can be regulated in an infinitely variable manner. The components of the traction power converter are coupled via one or more intermediate circuits.

The traction power converter for a system for operating on alternating current power grids is composed of at least one H bridge, at least one intermediate circuit that is operated with direct voltage and one pulse width modulated inverter and, if appropriate, at least one braking controller. In the case of operation with a direct voltage power grid, the H bridge can be dispensed with, and instead the intermediate circuit is connected to the power grid via at least one line choke. If the inverter can transmit energy in both directions of rotation, from the intermediate circuit to the motor and also back into the intermediate circuit during braking, then the term four-quadrant operation is used.

The intermediate circuit is an electrical device that electrically couples, as an energy accumulator, a plurality of electrical subsystems (e.g., H bridges to pulse width modulated inverters) at an intermediately connected current level or voltage level. In the text which follows, only voltage intermediate circuits (i.e., intermediate circuits with intermediate circuit capacitors) are considered. The intermediate circuit can only store a specific amount of energy without destruction. Consequently, measures for reducing the stored energy have to be taken. One way is to convert the electrical energy into thermal energy with a special form of a power converter, specifically what is referred to as a braking chopper. The braking chopper is usually composed of an IGBT as an electronic switch, a resistor and free-wheeling diodes. The electronic switch can connect a resistor to the intermediate circuit. Through periodic switching on (clocking) of the switch, current flows through the resistor and electrical energy is converted into heat. This serves, for example, to limit the voltage in the intermediate circuit.

The semiconductor switches in contemporary power converters (e.g., pulse width modulated inverters, H bridges) and braking choppers in railroad operations are formed as Si IGBTs, i.e., IGBTs based on silicon. Owing to limitations of the minimum lead times, the switching times and the switching losses in the application field of traction inverters such IGBTs can be operated only with relatively low switching frequencies, generally of 100 to 1500 Hz.

There are known SiC semiconductor components, i.e., semiconductor components based on silicon carbide in the power classes that are relevant for the field of railroad power converters. In comparison to Si IGBTs or Si semiconductor components, SiC semiconductor components have lower switching losses, shorter switching times and smaller limitations on the lead time. This permits the switching frequency of SiC semiconductor components to be raised in comparison with Si semiconductor components.

SiC semiconductor components, such as SiC MOSFETs, can therefore be operated as Si IGBTs in the application field of traction inverters with relatively high switching frequencies. SiC MOSFETs can be operated in said field with, e.g., 100-8000 Hz.

One possibility would be to then replace all the Si IGBTs in the power converters and the braking choppers with SiC semiconductor components, such as MOSFETs, in the field of railroads, and to raise the switching frequency. This would be advantageous for the inductive components, such as motors or transformers or chokes that are connected to power converter or converters. In addition, this would reduce the voltage ripple in the intermediate circuit that is caused by the clocking of the braking chopper. The intermediate circuit could then be provided with a relatively low capacitance, i.e., with a relatively small intermediate circuit capacitor, for example.

In addition to the voltage ripple which is caused by the braking chopper, the capacitance of the intermediate circuit capacitor in the field of railroads is determined by means of superimposed system requirements (e.g. input-side impedance of the line choke and intermediate circuit capacitor in the case of a DC vehicle). These and other system requirements of the capacitance of the intermediate circuit generally have priority over the requirement for low voltage ripple. In this respect, a combination of a power converter using SiC components with a braking chopper using SiC components is therefore technically inappropriate.

### SUMMARY OF THE INVENTION

In view of the foregoing, it is therefore an object of the present invention to provide a voltage supply device that uses, in a technically appropriate way, the advantage of components that clock at a relatively high rate, e.g., SiC components, for a voltage supply device for railroad drives.

This and other objects and advantages are achieved in accordance with the invention by a voltage supply device having at least one intermediate circuit comprising at least one intermediate circuit capacitor, at least one power converter, where the power converter is connected to the connections of the intermediate circuit such that the power converter can be supplied with electrical energy from the intermediate circuit capacitor, and/or such that the power converter can feed electrical energy into the intermediate circuit, and at least one braking chopper that is connected to the connections of the intermediate circuit capacitor such that electrical energy of the intermediate circuit capacitor can be converted into thermal energy by the braking chopper, where the power converter is equipped with at least one semiconductor switch that is clocked at a relatively high rate, while the braking chopper is equipped with at least one semiconductor switch that is clocked at a relatively low rate.

The term clocking at a relatively high rate is meant to mean the clocking frequency is higher than in the semiconductor switch of the braking chopper, and the term clocking at a relatively low rate is meant to mean the clocking frequency is lower than in the case of the semiconductor switch of the power converter (for example, H bridge and/or pulse width modulated inverter).

In particular, it can be provided that the power converter is equipped with at least one semiconductor switch that clocks at a relatively high rate and is based on SiC, while the braking chopper is equipped with at least one semiconductor switch that clocks at a relatively low rate and that is based on Si.

Therefore, the power converter or converters, for example, pulse width modulated inverters and/or H bridges are equipped with SiC semiconductor switches, in particular SiC MOSFETs, while the braking chopper or choppers are equipped with Si semiconductor switches, in particular with Si IGBTs, which have a relatively slow clocking rate.

SiC MOSFETs are currently technically more complex to manufacture and therefore currently more expensive than Si IGBTs. For use in pulse width modulated inverters or H bridges, it is worth incurring the additional expenditure and the additional costs for new kinds of SiC MOSFETs because as a result the efficiency of the overall system, composed of a power converter and connected components, such as chokes, motors and transformers, can be increased.

In contrast, for use in a braking chopper, the use of SiC MOSFETs is less worthwhile because an increased switching frequency generally does not provide an advantage, e.g., for the intermediate circuit capacitor, because its configuration is predominantly affected by imposed system requirements. On the contrary, the braking chopper is intended to convert electrical energy into heat, so that energy-efficient SiC components would be less appropriate here.

In one embodiment of the invention, the power converter (such as a pulse width modulated inverter and/or H bridge) is equipped with at least one SiC MOSFET. If a power converter has precisely one semiconductor switch, then it is therefore preferably formed as a SiC MOSFET.

In addition, for this purpose the braking chopper is preferably equipped with at least one Si IGBT. If the braking chopper has precisely one semiconductor switch, then it is preferably formed as a Si IGBT.

A voltage supply device in accordance with the invention can contain a plurality of power converters at the connections (e.g. tunnels) of the intermediate circuit. In one embodiment of the invention, at least one power converter is formed as a pulse width modulated inverter. Alternatively or additionally, at least one power converter is formed as an H bridge.

It is particularly advantageous if all the power converters (in particular, pulse width modulated inverters and/or H bridges) are equipped exclusively with semiconductor switches that clock at a relatively high rate (in comparison with the semiconductor switch of the braking chopper) and are based on SiC.

It is particularly advantageous if all the braking choppers are equipped only with semiconductor switches that clock at a relatively low rate (in comparison with the semiconductor switch of the power converters) and are based on Si.

The voltage supply device according to the invention is advantageously used in the drive of a railroad.

Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

The invention will now be explained in more detail with reference to preferred exemplary embodiments. The drawings are exemplary and are intended to illustrate the inventive idea but not to restrict it in any way or even represent it conclusively, in which:

FIG. 1 shows a voltage supply device in accordance with the invention in a DC vehicle;

FIG. 2 shows a braking chopper in accordance with the invention with Si IGBT;

FIG. 3 shows a graphical plot of the current profile and voltage profile plotted against the time for the braking chopper of FIG. 2;

FIG. 4 shows a braking chopper with a SiC MOSFET in accordance with the invention; and

FIG. 5 shows a graphical plot of the current profile and voltage profile plotted against the time for the braking chopper from FIG. 4.

### DETAILED DESCRIPTION OF THE EXEMPLARY EMBODIMENTS

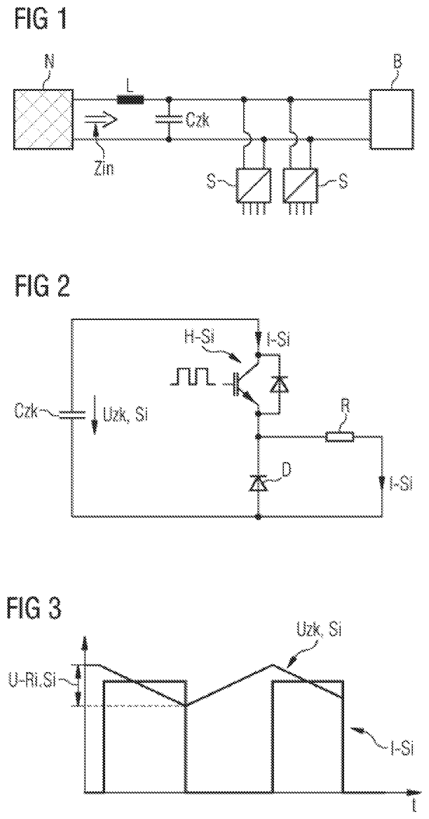

FIG. 1 shows a voltage supply device in accordance with the invention that is connected to a power grid N, here a DC power grid. On the grid side, the voltage supply device comprises a line choke L and an intermediate circuit with an intermediate circuit capacitor Czk. In a vehicle that is supplied with an alternating voltage, the intermediate circuit is fed via an H bridge instead of the line choke, where the transformer that is usually mounted upstream would again constitute an inductor.

Viewed from the power grid N, the voltage supply device has an input impedance Zin. Two power converters S, e.g., pulse width inverters and/or H bridges, are connected to the terminals of the intermediate circuit capacitor Czk here. It would also be possible to connect further power converters as indicated by the dots. Furthermore, at least one braking chopper B is connected to the terminals of the intermediate circuit capacitor Czk. Other braking choppers B could also be connected.

The braking chopper B from FIG. 1 is illustrated in FIG. 2. The braking chopper B is connected in parallel with the intermediate circuit capacitor Czk, and the voltage Uzk,Si is present at the intermediate circuit capacitor Czk. The braking chopper B comprises a semiconductor switch H-Si that is based on Si and through which the current I-Si flows. The control signal for the semiconductor switch H-Si is illustrated to the left of the semiconductor switch H-Si as a rectangular function plotted over time. Furthermore, the braking chopper B has a resistor R and a free-wheel diode D parallel thereto.

In FIG. 3, the current profile and voltage profile are illustrated plotted against the time t for the braking chopper B from FIG. 2. The current profile shows the periodic profile of the current I-Si, resulting from the control signal, through the semiconductor switch H-Si. This results in the triangular profile of the voltage Uzk,Si in the intermediate circuit. The distance between the highest and the lowest voltage values denotes the voltage ripple U-Ri,Si (see double arrow) owing to the current I-Si.

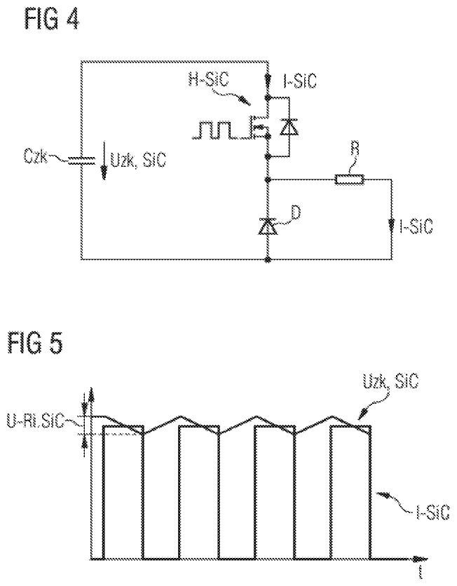

If a semiconductor switch H-SiC that is based on SiC, such as a SiC MOSFET, were also to be installed in the braking chopper B, as in the power converters S, the rest of the circuit remains fundamentally as in FIG. 2, see FIG. 4. However, the control signal for the semiconductor switch H-SiC, which is again a square-wave function, could have a higher frequency than for the semiconductor switch H-Si which is based on Si in FIG. 2.

Correspondingly, the current I-SiC through the semiconductor switch H-SiC and the voltage Uzk,SiC in the intermediate circuit or at the intermediate circuit capacitor Czk would change correspondingly, see FIG. 5. In the figure, the current profile and voltage profile are illustrated again plotted against the time t for the braking chopper B from FIG. 4.

The current profile shows the periodic stepped profile of the current I-SiC, resulting from the control signal, through the semiconductor switch H-SiC. The current I-SiC has a higher frequency than the current I-Si in FIG. 3. Correspondingly, the triangular profile of the voltage Uzk,SiC in the intermediate circuit has a higher frequency than that of the voltage Uzk,Si in FIG. 3. The distance between the highest and the lowest voltage values denotes the voltage ripple U-Ri,SiC owing to the current I-SiC. Although the voltage ripple is lower than that in FIG. 3, the advantages which can be achieved thereby do not outweigh the disadvantage of higher procurement costs of the SiC semiconductor switch H-SiC.

Thus, while there have been shown, described and pointed out fundamental novel features of the invention as applied to a preferred embodiment thereof, it will be understood that various omissions and substitutions and changes in the form and details of the methods described and the devices illustrated, and in their operation, may be made by those skilled in the art without departing from the spirit of the invention. For example, it is expressly intended that all combinations of those elements and/or method steps which perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

1.-9. (canceled)

10. A voltage supply device comprising:
at least one intermediate circuit comprising at least one intermediate circuit capacitor;
at least one power converter which is connected to connections of the at least one intermediate circuit such that at least one of (i) the power converter is supplied with electrical energy from the intermediate circuit capacitor (ii) the power converter feeds electrical energy into the at least one intermediate circuit; and
at least one braking chopper which is connected to the connections of the at least one intermediate circuit capacitor such that electrical energy of the at least one intermediate circuit capacitor is convertible into thermal energy by the at least one braking chopper;
wherein the power converter includes at least one semiconductor switch which is clocked at a relatively high rate, and the braking chopper includes a semiconductor switch which is clocked at a relatively low rate.

11. The voltage supply device as claimed in claim 10, wherein the power converter includes at least one semiconductor switch which is clocked at a relatively high rate and is based on SiC, and the braking chopper includes at least one semiconductor switch which is clocked at a relatively low rate and is based on Si.

12. The voltage supply device as claimed in claim 10, wherein the power converter includes at least one SiC MOSFET.

13. The voltage supply device as claimed in claim 11, wherein the power converter includes at least one SiC MOSFET.

14. The voltage supply device as claimed in claim 10, wherein the braking chopper includes at least one Si insulated-gate bipolar transistor.

15. The voltage supply device as claimed in claim 10, wherein at least one power converter is formed as a pulse width modulator.

16. The voltage supply device as claimed in claim 10, wherein at least one power converter is formed as an H bridge.

17. The voltage supply device as claimed in claim 10, wherein all power converters of the voltage supply device exclusively include semiconductor switches which are clocked at a relatively high rate and which are based on SiC.

18. The voltage supply device as claimed in claim 10, wherein all braking choppers of the voltage supply device exclusively include semiconductor switches which are clocked at a low rate and are based on Si.

19. The voltage supply device as claimed in claim 10, wherein the voltage supply device powers a railroad.
